(19) United States
(12) Patent Application Publication
(10) Pub. No.: US 2025/0251467 A1
(43) Pub. Date: Aug. 7, 2025

(54) SYSTEMS AND METHODS FOR MONITORING AND MANAGING ELECTRICAL CONDUITS OF POWER DELIVERY SYSTEMS

(71) Applicant: Lenovo Global Technology (United States) Inc., Morrisville, NC (US)

(72) Inventors: Robert Wolford, Morrisville, NC (US); Brian C. Totten, Morrisville, NC (US)

(21) Appl. No.: 18/429,580

(22) Filed: Feb. 1, 2024

(51) Int. Cl. G01R 31/54; G01R 31/58; H02H 7/26

(52) U.S. Cl. CPC G01R 31/54; G01R 31/58; H02H 7/26

(57) ABSTRACT

Systems and methods for monitoring and managing electrical conduits of power delivery systems are disclosed. According to an aspect, a system includes electrical conduction sensors that are each configured for operative connection to one electrical conduit among electrical conduits of a power delivery system. Each electrical conduction sensor is configured to detect whether electrical conduction of its respective electrical conduit meets a predetermined criterion. The system also includes a power delivery manager configured to implement a predetermined action in response to detection, by one of the electrical conduction sensors, that electrical conduction of its respective electrical conduit meets the predetermined criterion.

### TECHNICAL FIELD

The presently disclosed subject matter relates generally to power supply management and monitoring systems. Particularly, the presently disclosed subject matter relates to systems and methods for monitoring and managing electrical conduits of power delivery systems.

### BACKGROUND

Power cables are used in a variety of systems for transmission of electrical power from a power source to an electronic device. For example, a power cable may be used to connect a power outlet, power strip, or battery to a computing device, such as a server, laptop computer, desktop computer, display, printer, or other such electronic device. A power cable typically includes two connector ends for engaging the power source and electronic device. Electrical conduits, such as wires, can extend between the connector ends for providing electrical power transmission pathways between the ends.

Some power cables include multiple electrical conduits (wires) that split current among the wires, rather than having one large conduit or a few conduits. These designs are often used in applications in which more flexibility of the power cable is needed, or to allow a connector to fit within a specific volume. With these designs, an issue may arise if one or more of the power cable conduits breaks such that the remaining conduits need to carry the same current load. In such cases, the rated current of the remaining conduits can be exceeded such that a hazardous condition is presented.

The aforementioned issue of conduit failure has been addressed by over-designing the power cable such that if one conduit breaks or fails, there is still enough capacity in the remaining conduits to safely handle the increased current load. However, this design can make the overall size of the power cable much larger since large gauge conduit is needed for every conduit in the power cable. Also, an operator may still be unaware in the case of conduit failure. If additional conduits break, then the remaining conduits can become overloaded.

In view of the foregoing, there is a need for improved systems and techniques for monitoring and managing power cables.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 is a block diagram of a system for monitoring and managing electrical conduits of a power delivery system in accordance with embodiments of the present disclosure;

FIG. 2 is a schematic diagram of an electrical conduction sensor in accordance with embodiments of the present disclosure;

FIG. 3 is a schematic diagram of a power delivery manager and electrical conduction sensors connected with four electrical conduits for monitoring conductivity in accordance with embodiments of the present disclosure;

FIG. 4 is a flow diagram of a method for monitoring and managing electrical conduits of a power delivery system in accordance with embodiments of the present disclosure; and

FIG. 5 is a diagram of an example environment for a system for monitoring and managing wires of a power cable in accordance with embodiments of the present disclosure.

### SUMMARY

The presently disclosed subject matter relates to systems and methods for monitoring and managing electrical conduits of power delivery systems. According to an aspect, a system includes electrical conduction sensors that are each configured for operative connection to one electrical conduit among electrical conduits of a power delivery system. Each electrical conduction sensor is configured to detect whether electrical conduction of its respective electrical conduit meets a predetermined criterion. The system also includes a power delivery manager configured to implement a predetermined action in response to detection, by one of the electrical conduction sensors, that electrical conduction of its respective electrical conduit meets the predetermined criterion.

According to another aspect, a method includes using electrical conduction sensors to detect whether each electrical conduit among a plurality of electrical conduits meets a predetermined criterion. The method also includes implementing a predetermined action in response to detection, by one of the electrical conduction sensors, that electrical conduction of its respective electrical conduit meets the predetermined criterion.

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

Unless otherwise defined, all technical terms used herein have the same meaning as commonly understood by one of ordinary skill in the art to which this disclosure belongs.

As referred to herein, the term “electronic device” may include any type of device having electrical hardware or circuitry. For example, an electronic device may be referred to as a computing device. Example electronic device may include, but is not limited to, a server, a desktop computer, a laptop computer, a smart phone, a cell phone, a pager, a personal digital assistant (PDA, e.g., with GPRS NIC), a mobile computer with a smartphone client, or the like.

As referred to herein, the term “power delivery system” can be any system operable to transmit or deliver electrical power from a power source to an electronic device. For example, a power delivery system can include, but is not limited to, power delivery system comprises a power cable, printed circuit board (PCB) traces, a busbar, a mechanical fastener, a crimped connector, soldered connectors, or the like. The power delivery system can include multiple electrical conduits for delivery power from a power source to an electronic device. For example, electrical conduits may be multiple wires that split or divide the current. For example, one or more wires of a power cable may carry positive voltage, and one or more other wires may carry negative voltage or be connected to ground. Typically, power cable and wires are covered by non-conductive material, such as plastic. A power delivery system, such as a power cable, can include two opposing ends with connectors for operatively interfacing with a power source and an electronic device.

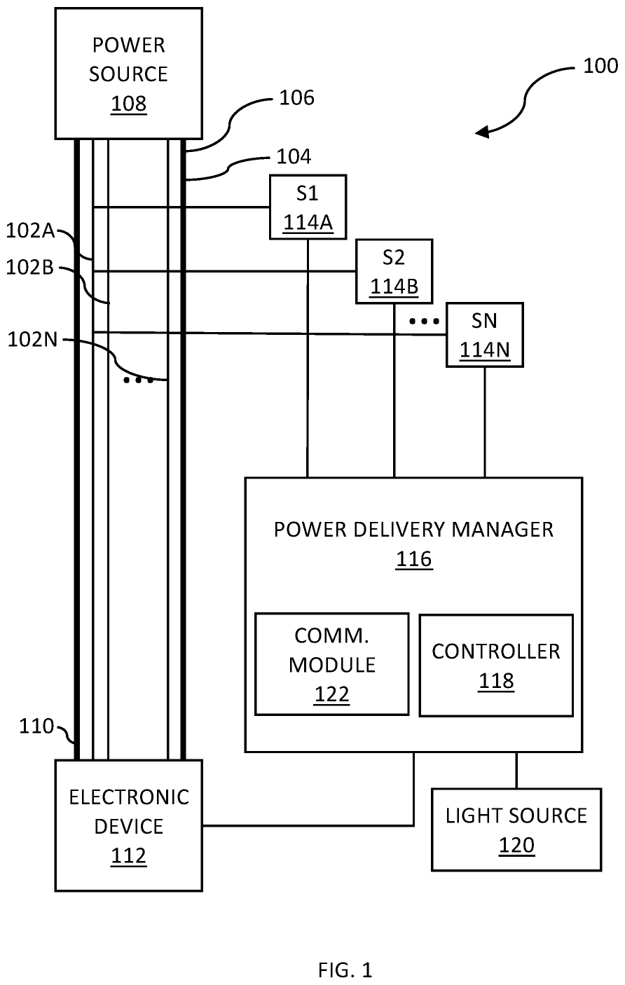

FIG. 1 illustrates a block diagram of a system 100 for monitoring and managing electrical conduits 102A-102N of a power delivery system 104 in accordance with embodiments of the present disclosure. In this example, the power delivery system 104 is a power cable, but it should be appreciated that the power delivery system 104 may alternatively be any other suitable system or equipment for delivery power between its endpoints. Referring to FIG. 1, the power cable 104 includes one connector end 106 that is operatively connected to (or plugged into) a power source 108 (e.g., electrical outlet or power strip). The power cable 104 also include another connector end 110 that is on an opposing end of the power cable 104. The connector end 110 is operatively connected to (or plugged into) an electronic device 112 (e.g., server or other computer). The power source 108 may be a power outlet, battery, or other suitable power source (e.g., AC power source) having a connection (e.g., plug-in) for the connector end 106 of the power cable 106. Also, the electronic device 112 may have a suitable interface for connecting to the power cable 106. When the power source 108 and the electronic device 112 are operatively connected to the power cable 106, the power source 108 can suitably provide power to the electronic device 112 via transmission of current via the electrical conduits 102A-102N of the power cable 106.

Each electrical conduit 102A-102N may be an individual, insulated wire that conductively connects the power source 108 to the electronic device 112. The electrical conduit can be any part of the end-to-end path used to deliver current to the electronic device. It can include the wires, connectors, terminals, and the like. As an example, one or more of the electrical conduits 102A-102N can be positive wires for carrying positive voltage, and one or more others of the electrical conduits 102A-102N can be negative wires. A negative wire may be for ground connection. Collectively, the electrical conduits 102A-102N function to deliver power to the electronic device 112.

The system 100 includes electrical conduction sensors S1-SN indicated by references 114A-114N. The electrical conduction sensors 114A-114N are operatively connected to electrical conduits 102A-102N, respectively. In particular, an individual one of the electrical conduction sensors 114A-114N is operatively connected to a respective one of the electrical conduits 102A-102N. Each electrical conduction sensor 114A-114N is configured to detect whether electrical conduction of its respective electrical conduit 102A-102N meets a predetermined criterion. For example, each electrical conduction sensor may detect whether a current level through its respective electrical conduit is less than a current threshold. For example, the electrical conduction sensor can detect whether there is no current or a nominal current such that it can be assumed that the electrical conduit is broken such that it is not conductive, not sufficiently conductive, or damaged such that it can be considered non-functional.

An electrical conduction sensor (one of sensors 114A-114N) can be any suitable sensor operable to detect or sense current transmitted through a connected electrical conduit. In accordance with embodiments, a sensor may include a sense resistor (not shown) placed in series along with an electrical conduit that is being monitored. The sense resistor may have a small resistance value so that it only dissipates minimal power from the electrical conduit. It is noted that since binary sensing (i.e., the electrical conduit is conductive or not conductive) then accuracy may not be important in some instances. The electrical conduction sensor may also include a comparator circuit (not shown) that is operable to sense a differential voltage across its sense resistor. In an example, if the comparator circuit senses that a current flow through the sense resistor is below a threshold level, then the comparator circuit's output is logic 0 (e.g., 0 volts). If the comparator circuit senses that the current flow through the sense resistor is above the threshold level, the comparator circuit's output is driven to logic 1 (e.g., V_{cc}). It is noted that the comparator circuit's current trip level (or threshold) can be set high enough above 0 volts such that the comparator circuit is out of its unknown state and to maintain adequate noise margin so that false positive electrical conduit breaks are not detected. Outputs of electrical conduction sensors 114A-114N can be operatively connected to a power delivery manager 116 for indicating whether current through each electrical conduit 102A-102N is above or below the threshold.

The power delivery manager 116 is configured to implement a predetermined action in response to detection, by one of the electrical conduction sensors 114A-114N, that electrical conduction of its respective electrical conduit (one of electrical conduits 102A-102N) meets a predetermined criterion. In accordance with embodiments, the power delivery manager 116 can include an AND gate (not shown) having inputs that are operatively connected to outputs of the electrical conduction sensors 114A-114N. For example, the AND gate inputs can each be connected to a respective one of the comparator circuit outputs of the electrical conduction sensors 114A-114N. Thus, the AND gate inputs each receives input of logic 1 when its respective electrical conduit is sufficiently conductive (i.e., not damaged), and the AND gate inputs each receives input of logic 0 when its respective electrical conduit is not conductive or not sufficiently conductive (i.e., the electrical conduit is broken, damaged, or otherwise not functional). If any of the electrical conduits 102A-102N are sensed as having insufficient current flow, then an input into the AND gate is logic 0, and in this scenario the AND gate's output is 0 logic to indicate the condition of a broken, damaged, or otherwise non-functional electrical conduit. Otherwise, if all the inputs to the AND gate are logic 1, the AND gate's output is logic 1 to indicate that all of the electrical conduits 102A-102N are suitably operational. It is noted that to provide noise immunity, a Schmitt-trigger AND gate or other suitable AND gate may be utilized.

The power delivery manager 116 can include a controller 118 that implements the predetermined action in response to an indication that one or more of the electrical conduits 102A-102N are not suitably operational (e.g., does not sufficiently conduct due to being broken or damaged). For example, the controller 118 may drive a light source 120 (e.g., light emitting diode (LED)) or other indicator in response to the indication that one of the electrical conduits 102A-102N is not operational. In another example, the controller 118 may be connected to other circuitry or logic for implementing another action in response to the indication that one of the electrical conduits 102A-102N is not operational. In an example, the controller 118 may utilize a communication module 122 to send notification to a computing device to inform an operator of the condition. For example, the communication module 122 may send a communication to report the error to one or more operators. In another example, the controller 118 can prevent the electronic device 112 from turning on in response to the indication that one of the electrical conduits 102A-102N is not operational. As a result of detecting conductivity of each electrical conduit 102A-102N, suitable action can be taken for mitigating the issue. For example, an operator can replace or repair the cable 104.

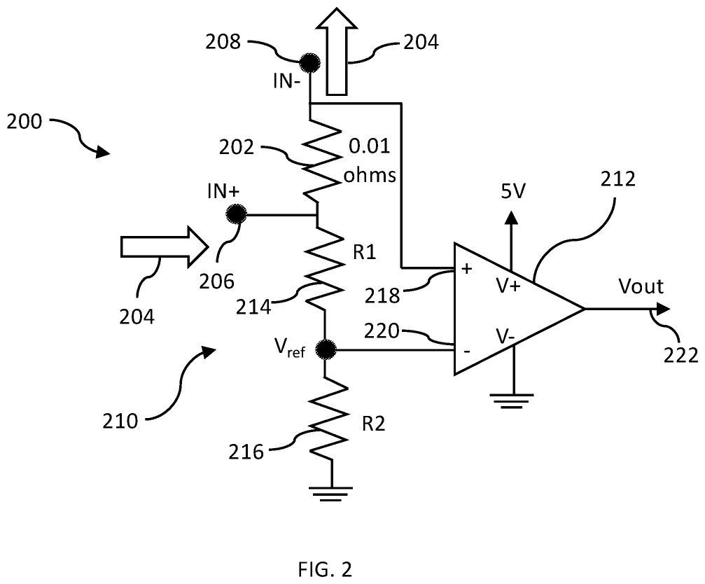

FIG. 2 illustrates a schematic diagram of an electrical conduction sensor 200 in accordance with embodiments of the present disclosure. For example, the sensor 200 may be one of the electrical conduction sensors 114A-114N utilized in the system 100 shown in FIG. 1. In the use case of FIG. 1, a sensing resistor 202 can be placed in series with one of the electrical conduits 102A-102N for detecting current flow (indicated by arrows 204) through its respective electrical conduit. In this example, current enters at input (IN+) 206, flows through sensing resistor 202, and out at output (IN−) 208.

The electrical conduction sensor 200 also includes a comparator circuit, generally designated 210, configured to sense a differential voltage across the sense resistor 202. The comparator circuit 210 includes a differential amplifier 212 that operates together with divider resistors R1 and R2 (designated 214 and 216, respectively). In this example, the differential amplifier 212 includes + and − inputs, designated 218 and 220, respectively, and an output Vₒᵤₜ 222. +input 218 is connected to one end of the sending resistor 202. −input 220 is connected between resistors R1 and R2 214, 216. Resistor R2 216 is connected at its other end to ground as shown. Another end of resistor R1 214 is connected to the sensing resistor 202 as shown. In the arrangement shown in FIG. 2 and with resistors 202, 214, and 216 having suitable values, the comparator circuit 210 can determine whether there is current flow or no current flow based on the sensed differential voltage; and output a signal at its output that is indicative of a determination of current flow or no current flow. The output of the comparator circuit 210 is driven to logic 1 if it determines that the current flow is above a threshold level, and the output is logic 0 if it determines that the current flow is below the threshold level.

Table 1 below shows example values for resistors shown in the embodiment of FIG. 2 for setting a threshold level for current flow.

TABLE 1

| Current | | | | | |
|---|---|---|---|---|---|
| Threshold | | V_{ref} (reference | | R1, actual | R2, actual |
| Level | | 224 in FIG. 1) | R2/R1 | (+/−5%) | (+/−5%) |
| 100 | mA | 12 V − 1 mV = | 11999 | 1 | 12000 |
| | | 11.999 V | | | |
| 500 | mA | 12 V − 5 mV = | 2400 | 1 | 2400 |
| | | 11.995 V | | | |
| 1 | A | 12 V − 10 mV = | 1199 | 1 | 1200 |

11.99 V

Turning to Table 1, the table shows 3 example current threshold levels: 100 mA, 500 mA, and 1 A. In each example, sensing resistor 202 is set at 0.01 ohms, but it should be understood that the value of this sensing resistor 202 may have any other suitable value and the values of resistors R1 and R2 (214 and 216) can be adjusted accordingly for achieving a desired current threshold level. In these examples, the table shows calculation of a minimum voltage V_{ref} across the sensing resistor 202 for meeting or exceeding the current threshold level. The table also shows the ratio (R2/R1) of resistor values for the comparator circuit 210, and example R1 and R2 values. With these resistor values in the arrangement shown in FIG. 2, the output Vₒᵤₜ 222 goes high to logic 1 if the current flow 204 exceeds the current threshold level. This indicates that current greater than the current threshold level is flowing through the corresponding electrical conduit (e.g., power cable pin) and the connection is intact. Conversely, output Vₒᵤₜ 222 goes low to logic 0 if the current flow 204 is less than the current threshold level.

In an example configuration for connecting the electrical conduction sensor 200 shown in FIG. 2, input (IN+) 206 is connected to 12 V pin from a power source (e.g., power source 108 shown in FIG. 1), and its ground pin connected to the power cable pin. Further in this example, output (IN−) 208 is connected to the power cable pin, and its ground pin connected to the power source.

In accordance with embodiments, a system for monitoring and managing electrical conduits may be arranged for indicating that current flow in one or more of the electrical conduits of a power delivery system exceeds a current threshold level. This condition can indicate that at least one of the other electrical conduits is broken or otherwise non-functional such that the other electrical conduits are carry excessive current. This can be another technique for determining that criterion is not met and thus a predetermined action can be implemented by the power delivery manager 116. In an example, the electrical conduction sensor 200 shown in FIG. 2 may be configured with different values for resistors R1 and R2 214 and 216 for implementing these embodiments. Table 2 below shows example values for resistors shown in the embodiment of FIG. 2 for setting a threshold level for current flow that indicates a maximum level is exceeded. It is noted that in this example, the value of the sensing resistor is 0.01 ohms, but it may alternatively be any other suitable value.

TABLE 2

| Current | | | | |
|---|---|---|---|---|
| Threshold | V_{ref} (reference | | R1, actual | R2, actual |
| Level | 224 in FIG. 1) | R2/R1 | (+/−5%) | (+/−5%) |
| 2 A | 12 V − 0.02 V = | 599 | 100 | 62K |
| | 11.98 V | | | |
| 4 A | 12 V − 0.04 V = | 299 | 100 | 30K |
| | 11.96 V | | | |
| 8 A | 12 V − 0.08 V = | 149 | 100 | 15K |
| | 11.92 V | | | |

Turning to Table 2, the table shows 3 example maximum threshold levels at which output Vₒᵤₜ 222 goes high to logic 1:2 Amps, 4 Amps, and 8 Amps. In an example to calculate a maximum current threshold level, a power rating of a power cable including multiple wires can be determined (e.g., by its listed specification). This may be used to calculate a rated maximum current level for each wire (i.e., electrical conduit). In one example, if a power cable has 4 wires with 2 being 12 V and 2 being ground, then the maximum current per 12V wire can be the current rating of the cable divided by 2.

In a system with electrical conduction sensors that indicate a current threshold level of an electrical conduit has been exceeded, the power delivery manager 116 can implement a predetermined in response to detection that the current level threshold is exceeded for any one of the electrical conduits. For example, the power delivery manager 116 as shown in FIG. 1 can receive the indications from each sensor about whether its respective current level threshold is exceeded. In the case of at least one being exceeded, then the power delivery manager 116 can implement a predetermined action in accordance with embodiments of the present disclosure. For example, the power delivery manager 116 can control the light source 120 to indicate the condition, and/or utilize the communication module 122 to send notification of the condition to an operator.

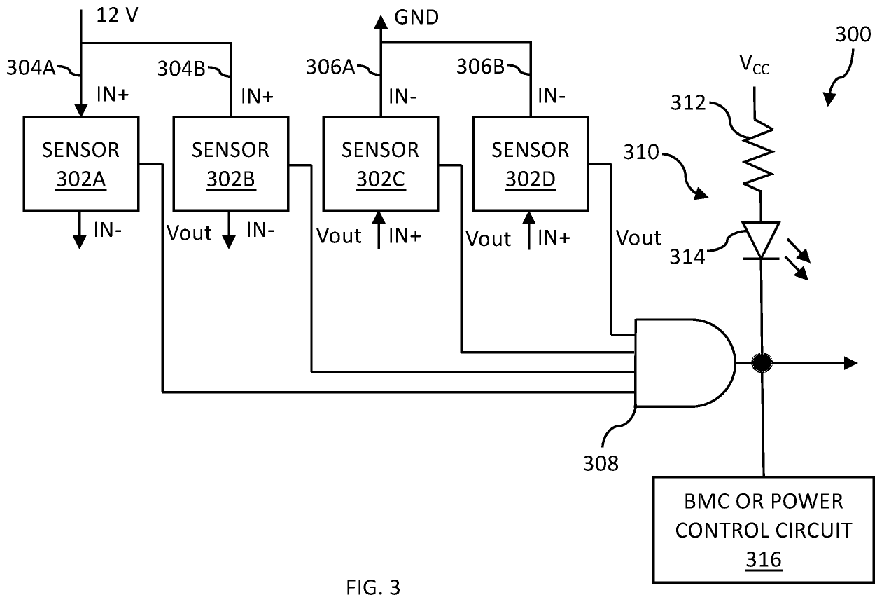

FIG. 3 illustrates a schematic diagram of a power delivery manager 300 and electrical conduction sensors 302A, 302B, 302C, and 302D connected with four electrical conduits for monitoring conductivity in accordance with embodiments of the present disclosure. Referring to FIG. 3, electrical conduction sensors 302A, 302B, 302C, and 302D are operatively connected to wires of a power cable. It is noted that wires 304A-304D of the power cable are shown, but it should be appreciated that the power cable may include other wires. Electrical conduction sensors 302A and 302B are operatively connected to 2 wires (designated 304A and 304B, respectively) of the power cable that are connected to a 12 V power supply, and conduction sensors 302C and 302D are operatively connected to 2 ground wires (designated 306A and 306B, respectively) of the power cable. Each electrical conduction sensor 302A-302D may, for example, include a sensing resistor placed in series with its respective wire (wires 304A, 304B, 306A, and 306B, respectively) for use in detecting whether current through its respective wire is below a threshold level as described examples herein. In response to detecting that the current level through its respective wire is 0 amperes or less than a current threshold, then the output Vout of the electrical conduction sensor can be logic 0. Conversely, in response to detecting that the current level through its respective wire is greater than or equal to a current threshold, then the output Vout of the electrical conduction sensor can be logic 1. Thereby, each electrical conduction sensor is signaling logic 1 if the current is at an acceptable level (e.g., meaning the wire is operating as expected), and logic 0 is the current is below an acceptable level (e.g., meaning the wire may be damaged).

With continuing reference to FIG. 3, the sensing resistor for each electrical conduction sensor 302A and 302B is connected between IN− and IN+ for its respective wire. Also, the sensing resistor for each electrical conduction sensor 302C and 302D is connected between IN− and IN+ for its respective wire. It should be understood that any suitable electrical conduction sensor may be used for indicating that the wire's current is above or below a threshold level.

The power delivery manager delivery manager may include an AND gate 308 with inputs connected to the outputs of electrical conduction sensors 302A-302D. Thus, the AND gate 308 inputs each receives input of logic 1 when its respective electrical conduit is sufficiently conductive (i.e., not damaged), and the AND gate inputs each receives input of logic 0 when its respective electrical conduit is not conductive or not sufficiently conductive (i.e., the electrical conduit is broken, damaged, or otherwise not functional). If any of the electrical conduits 304A, 304B, 306A, and 306B are sensed as having insufficient current flow, then an input into the AND gate 308 is logic 0, and in this scenario the AND gate's output is 0 logic to indicate the condition of a broken, damaged, or otherwise non-functional electrical conduit. Otherwise, if all the inputs to the AND gate are logic 1, the AND gate's 308 output is logic 1 to indicate that all of the electrical conduits 304A, 304B, 306A, and 306B are suitably operational. It is noted that to provide noise immunity, a Schmitt-trigger AND gate or other suitable AND gate may be utilized.

The output of the AND gate 308 can be connected to a visual indicator 310 including a resistor 312 and light emitting diode (LED) 314 for indicating that at least one of the electrical conduits 304A, 304B, 306A, and 306B is broken, damaged, or otherwise a non-functional electrical conduit. The resistor 312 and LED 314 are connected in series between V_{cc} and the output of the AND gate 308 such that the LED 314 emits light on output of logic 0 from the AND gate 308 to thereby indicate an issue with at least one of the electrical conduits 304A, 304B, 306A, and 306B. Otherwise, on output of logic 1 from the AND gate 308, the LED 314 cannot be activated to thereby indicate no issued with any of the electrical conduits 304A, 304B, 306A, and 306B.

A controller, such as controller 118 shown in FIG. 1, can be operatively connected to the output of the AND gate 308 for receipt of either a logic 1 or logic 0 output. In this example, the controller can be a baseboard management controller (BMC) or other power control circuit 316 of a server or other computing device. The BMC 316 or other suitable controller can receive the output of the AND gate 308. In an example, the BMC 316 may utilize a communication module to send notification to a computing device to inform an operator of the condition. For example, the communication module may send a communication to report the error to one or more operators. In another example, the BMC 316 can prevent a server or other electronic device from turning on in response to receipt of logic 0. As a result of detecting conductivity of each electrical conduit, the BMC 316 may implement suitable action for mitigating the issue.

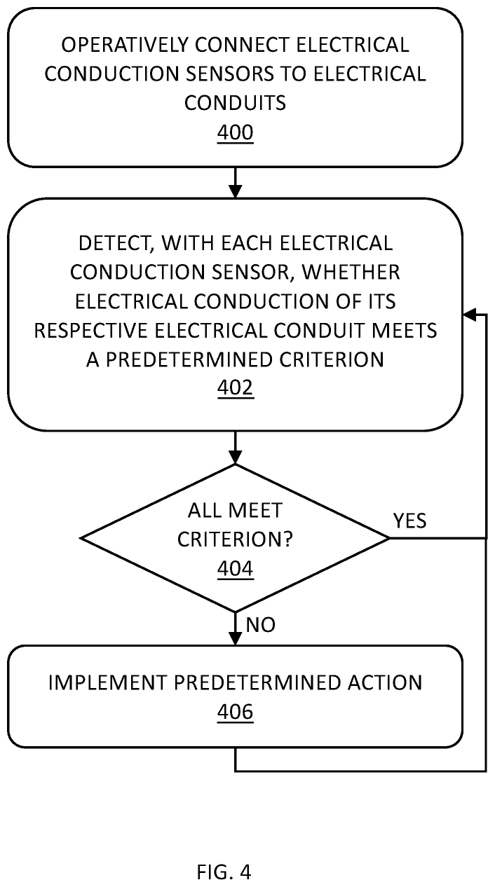

FIG. 4 illustrates a flow diagram of a method for monitoring and managing electrical conduits of a power delivery system in accordance with embodiments of the present disclosure. In this example, the method is described as being implemented by the system 100 shown in FIG. 1. However, it should be recognized that the method may be implemented by any other suitable system having electrical conduits.

Referring to FIG. 4, the method includes operatively connecting 400 electrical conduction sensors to electrical conduits. For example referring to FIG. 1, electrical conduction sensors 114A-114N can each be operatively connected to a respective one of the electrical conduits 102A-102N. The sensors 114A-114N can be connected to electrical conduits 102A-102N for detection of current transmitted in the conduits as described herein.

The method of FIG. 4 includes detecting 402, with each electrical conduction sensor, whether electrical conduction of its respective electrical conduit meets a predetermined criterion. Continuing the aforementioned example, each electrical conduction sensor 114A-114N can detect whether electrical conduction in its respective conduit is above or below a current threshold level. Each electrical conduction sensor 114A-114N can output a signal indicative of this detection. The controller 118 can receive each output.

The method of FIG. 4 can determine 404 whether all meet the criterion. Continuing the aforementioned example, the controller 118 can determine whether any of the outputs from electrical conduction sensors 114A-114N indicate a current below the current threshold level. In response to determining that any of the outputs indicate a current below the current threshold level, the method may proceed to step 406. Otherwise, in response determining that all of the outputs indicate a current above the current threshold level, the method may return to step 402 for continuing to monitor the detected current threshold levels.

At step 406, the method includes implementing a predetermined action. Continuing the aforementioned example, the controller 118 can utilize the communication module 122 to send notification to a computing device to inform an operator of the condition. In another example, the controller 118 can prevent the electronic device 112 from turning on. Subsequent to implementing the predetermined action, the method may return to step 402 for continuing to monitor the detected current threshold levels.

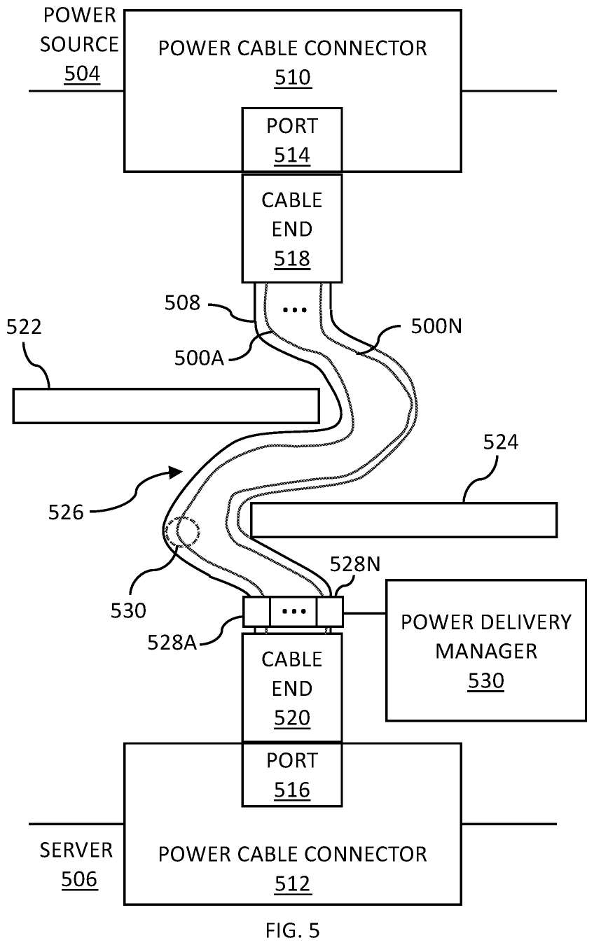

FIG. 5 illustrates a diagram of an example environment for a system for monitoring and managing wires 500A-500N of a power cable 502 in accordance with embodiments of the present disclosure. Referring to FIG. 5, power cable 502 includes multiple wires 500A-500N that extend between a power source 504 and a server 506. The wires 500A-500N are shielded and may include a non-conductive outer shield 508. There may be any number of wires A-N as part of the power cable 502. The power source 504 and the server 506 may include power cable connectors 510 and 512, respectively, for operatively connecting the power cable 508 therebetween. Particularly, each connector 510 and 512 may define ports 514 and 516, respectively, that mechanically receive cable ends 518 and 520, respectively, of ends of the power cable 508.

With continuing reference to FIG. 5, in this application of connecting the power cable 508 the power cable is routed around 2 obstacles 522 and 524. For example, such routing may be necessary to connect the power cable 508 to a power strip at one end, and to the server 506 at the other end. In this scenario, various obstacles may be in the way and it may be necessary for parts of the power cable 508 to be routed through narrow turns and passages, such as the passage indicated by reference 526. As a result, one or more of the wires 500A-500N may be damaged such that it becomes non-functional.

In accordance with embodiments, multiple electrical conduction sensors 528A-528N can be operatively connected to wires 500A-500N. Each sensor 528A-528N can detect whether electrical conduction of its respective wire 500A-500N, respectively, is greater than the current threshold level. Sensors 528A-528N can be operatively connected to a power delivery manager 530 for indicating whether electrical conduction of each wire is greater than the current threshold level. The power delivery manager 530 can implement a predetermined action (according to examples provided herein) in response to detection, by one of the sensors 528A-528N, that electrical conduction of one of the wires is not greater than the current threshold level. For example, wire 500A may be broken at an area designated 532. As a result, conduction by wire 500A may be less than the threshold such that it is detected and the predetermined action is implemented by the power delivery manager 530.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed is:

1. A system comprising:
a plurality of electrical conduction sensors that are each configured for operative connection to one electrical conduit among a plurality of electrical conduits of a power delivery system, wherein each electrical conduction sensor is configured to detect whether electrical conduction of its respective electrical conduit meets a predetermined criterion; and
a power delivery manager configured to implement a predetermined action in response to detection, by one of the electrical conduction sensors, that electrical conduction of its respective electrical conduit meets the predetermined criterion.

2. The system of claim 1, wherein the predetermined criterion is a current threshold,
wherein each electrical conduction sensor is configured to detect whether a current level through its respective electrical conduit is less than the current threshold, and
wherein the power delivery manager is configured to implement the predetermined action in response to detection by one of the electrical conduction sensors that the current level through its respective electrical conduit is less than the current threshold.

3. The system of claim 1, wherein each electrical conduction sensor is configured to detect whether a current level through its respective electrical conduit is 0 amperes, and
wherein the power delivery manager is configured to implement the predetermined action in response to detection by one of the electrical conduction sensors that the current level through its respective electrical conduit is 0 amperes.

4. The system of claim 1, wherein the electrical conduits include a positive wire for carrying positive voltage and a negative wire for ground connection.

5. The system of claim 1, wherein the electrical conduits are operatively connected to an electronic device and a power source for delivering power to the electronic device.

6. The system of claim 1, wherein each electrical conduction sensor comprises:
a resistor configured for connection in series with a respective electrical conduit of the electrical conduction sensor;
a comparator circuit operative configured to:
sense a differential voltage across the resistor;
determine whether there is current flow or no current flow based on the sensed differential voltage; and
output a signal indicative of a determination of current flow or no current flow.

7. The system of claim 6, wherein the resistor is a first resistor including a first end and a second end; and
wherein the comparator comprises:
a differential amplifier comprising a first and second inputs and an output, wherein the first input is operatively connected to the first end of the first resistor;
a second resistor comprising a first end and a second end, wherein the first end of the second resistor is operatively connected to the second end of the first resistor, and wherein the second end of the second resistor is operatively connected to the second input of the differential amplifier; and
a third resistor comprising a first end and a second end, wherein the first end of the third resistor is operatively connected to the second input of the differential amplifier, and wherein the second end of the third resistor is operatively connected to ground.

8. The system of claim 7, wherein the power delivery manager comprises an AND gate comprising a plurality of inputs and an output, wherein the output of each differential amplifier is operatively connected to a respective one of the inputs of the AND gate, and wherein the output of the AND gate indicates there is no current flow in any one of the electrical conduits.

9. The system of claim 8, comprising a light source operatively connected to the output of the AND gate for indicating current flow in all of the electrical conduits or no current flow in any one of the electrical conduits.

10. The system of claim 1, wherein the power delivery system comprises a power cable, printed circuit board (PCB) traces, a busbar, a mechanical fastener, a crimped connector, or soldered connectors.

11. The system of claim 1, wherein the power delivery manager is configured to communicate notification to an operator in response to detection by one of the electrical conduction sensors that the current level through its respective electrical conduit is less than the current threshold.

12. The system of claim 1, wherein the power delivery manager is configured to power down or prevent from powering up an electronic device operatively connected to the power cable in response to detection by one of the electrical conduction sensors that the current level through its respective electrical conduit is less than the current threshold.

13. A method comprising:
using a plurality of electrical conduction sensors to detect whether each electrical conduit among a plurality of electrical conduits meets a predetermined criterion; and
implementing a predetermined action in response to detection, by one of the electrical conduction sensors, that electrical conduction of its respective electrical conduit meets the predetermined criterion.

14. The method of claim 13, wherein the predetermined criterion is a current threshold,
wherein the method further comprises:
detecting, by each electrical conduction sensor, whether a current level through its respective electrical conduit is less than the current threshold; and
implementing the predetermined action in response to detection by one of the electrical conduction sensors that the current level through its respective electrical conduit is less than the current threshold.

15. The method of claim 13, wherein each electrical conduction sensor is configured to detect whether a current level through its respective electrical conduit is 0 amperes, and
wherein implementing the predetermined action comprises implementing the predetermined action in response to detection by one of the electrical conduction sensors that the current level through its respective electrical conduit is 0 amperes.

16. The method of claim 13, wherein the electrical conduits include a positive wire for carrying positive voltage and a negative wire for ground connection.

17. The method of claim 13, wherein the electrical conduits are operatively connected to an electronic device and a power source for delivering power to the electronic device.

18. The method of claim 13, wherein each electrical conduction sensor comprises:
a resistor configured for connection in series with a respective electrical conduit of the electrical conduction sensor;
a comparator circuit operative configured to:
sense a differential voltage across the resistor;
determine whether there is current flow or no current flow based on the sensed differential voltage; and
output a signal indicative of a determination of current flow or no current flow.

19. The method of claim 18, wherein the resistor is a first resistor including a first end and a second end; and
wherein the comparator comprises:
a differential amplifier comprising a first and second inputs and an output, wherein the first input is operatively connected to the first end of the first resistor;
a second resistor comprising a first end and a second end, wherein the first end of the second resistor is operatively connected to the second end of the first resistor, and wherein the second end of the second resistor is operatively connected to the second input of the differential amplifier; and
a third resistor comprising a first end and a second end, wherein the first end of the third resistor is operatively connected to the second input of the differential amplifier, and wherein the second end of the third resistor is operatively connected to ground.

20. The method of claim 13, wherein implementing the predetermined action comprises notifying an operator, or powering down or preventing from powering up an electronic device operatively to the electrical conduits.
